(19) United States
(12) Patent Application Publication
(10) Pub. No.: US 2018/0331713 A1
(43) Pub. Date: Nov. 15, 2018

(54) RADIO-FREQUENCY SWITCH HAVING INTERMEDIATE SHUNT

(71) Applicant: SKYWORKS SOLUTIONS, INC., Woburn, MA (US)

(72) Inventors: Zhiyang LIU, Dunstable, MA (US); Nuttapong SRIRATTANA, Billerica, MA (US); David Ryan STORY, Ladera Ranch, CA (US)

(21) Appl. No.: 15/972,164

(22) Filed: May 6, 2018

Related U.S. Application Data
(60) Provisional application No. 62/502,672, filed on May 6, 2017.

(51) Int. Cl. H04B 1/44; H01L 27/12; H03K 17/693; H01L 25/18

(52) U.S. Cl. CPC H04B 1/44; H01L 25/18; H03K 17/693; H01L 27/1203

(57) ABSTRACT

Radio-frequency switch having intermediate shunt. In some embodiments, a switch assembly can include a first stack and a second stack arranged in series between a first node and a second node, and defining an intermediate node between the first stack and the second stack. Each of the first stack and the second stack can include a respective number of transistors arranged in series. The switch assembly can further include a switchable shunt path having a first end coupled to the intermediate node such that the switchable shunt path is capable of connecting the intermediate node to a second end such as a ground. In some embodiments, the first and second stacks can be configured to be the same or be different.

### CROSS-REFERENCE TO RELATED APPLICATION(S)

This application claims priority to U.S. Provisional Application No. 62/502,672 filed May 6, 2017, entitled RADIO-FREQUENCY SWITCH HAVING INTERMEDIATE SHUNT, the disclosure of which is hereby expressly incorporated by reference herein in its entirety.

### BACKGROUND

### Field

The present disclosure relates to radio-frequency (RF) switches such as field-effect transistor (FET) based switches.

### Description of the Related Art

In electronics applications, field-effect transistors (FETs) can be utilized as switches. Such switches can allow, for example, routing of radio-frequency (RF) signals in wireless devices.

### SUMMARY

In some teachings, the present disclosure relates to a switch assembly that includes a first stack and a second stack arranged in series between a first node and a second node, and defining an intermediate node between the first stack and the second stack, with each stack including a respective number of transistors arranged in series. The switch assembly further includes a switchable shunt path having a first end and a second end, with the first end being coupled to the intermediate node such that the switchable shunt path is capable of connecting the intermediate node to the second end.

In some embodiments, the second end of the switchable shunt path can be configured to be coupled to a ground node. The switchable shunt path can include an intermediate shunt stack having a number of transistors arranged in series between the first end and the second end. The transistors in each of the first stack, the second stack, and the intermediate shunt stack can be field-effect transistors such that sources and drains of the field-effect transistors form the series arrangement of the respective stack.

In some embodiments, the field-effect transistors of the first stack and the second stack can be dimensioned approximately the same. The field-effect transistors of the intermediate shunt stack can be dimensioned differently than the field-effect transistors of the first stack and the second stack. In some embodiments, the field-effect transistors of the first stack, the second stack, and the intermediate shunt stack can be implemented as silicon-on-insulator devices.

In some embodiments, the number of transistors in the first stack can be different than the number of transistors in the second stack. The first node can be configured to receive a power-amplified signal for transmission, and the second node can be configured to be connected to an antenna for transmission of the power-amplified signal. In such a configuration, the number of transistors in the first stack can be greater than the number of transistors in the second stack. The number of transistors in the first stack can be selected to handle a power of the power-amplified signal, such as a low-power signal, present at the first node when each of the first and second stacks is turned off to disconnect the second node from the first node and the intermediate shunt stack is turned on. The number of transistors in the first stack and the number of transistors in the second stack can be selected to handle a power of the power-amplified signal, such as a high-power signal, present at the first node when each of the first and second stacks is turned off to disconnect the second node from the first node and the intermediate shunt stack is turned off.

In accordance with a number of implementations, the present disclosure relates to a switch die that includes a semiconductor substrate configured to allow formation of an integrated circuit, and a switching circuit implemented on the substrate. The switching circuit includes a first stack and a second stack arranged in series between a first node and a second node, and defining an intermediate node between the first stack and the second stack, with each stack including a respective number of transistors arranged in series. The switching circuit further includes a switchable shunt path having a first end and a second end, with the first end being coupled to the intermediate node such that the switchable shunt path is capable of connecting the intermediate node to the second end.

In some embodiments, the second end of the switchable shunt path can be configured to be coupled to a ground node. The switchable shunt path can include an intermediate shunt stack having a number of transistors arranged in series between the first end and the second end. The transistors in each of the first stack, the second stack, and the intermediate shunt stack can be field-effect transistors such that sources and drains of the field-effect transistors form the series arrangement of the respective stack. The field-effect transistors of the first stack, the second stack, and the intermediate shunt stack can be implemented as, for example, silicon-on-insulator devices.

In some embodiments, the number of transistors in the first stack can be different than the number of transistors in the second stack.

In some embodiments, the switch die can further include a control circuit configured to support operations of the first stack, the second stack, and the intermediate shunt stack. The control circuit can be configured to turn the first stack off, the second stack off, and the intermediate shunt stack on, when a low-power signal passes through the first node to a third node and it is desirable to isolate the second node from the first node. The control circuit is configured to turn the first stack off, the second stack off, and the intermediate shunt stack off, when a high-power signal passes through the first node to a third node and it is desirable to isolate the second node from the first node.

In some implementations, the present disclosure relates to a switching module that includes a packaging substrate configured to receive a plurality of components, and a switch assembly implemented on the packaging substrate. The switch assembly includes a first stack and a second stack arranged in series between a first node and a second node, and defining an intermediate node between the first stack and the second stack, with each stack including a respective number of transistors arranged in series. The switch assembly further includes a switchable shunt path having a first end and a second end, with the first end being coupled to the intermediate node such that the switchable shunt path is capable of connecting the intermediate node to the second end.

In some embodiments, the second end of the switchable shunt path can be configured to be coupled to a ground node. The switchable shunt path can include an intermediate shunt stack having a number of transistors arranged in series between the first and the second end. The transistors in each of the first stack, the second stack, and the intermediate shunt stack can be field-effect transistors such that sources and drains of the field-effect transistors form the series arrangement of the respective stack. The field-effect transistors of the first stack, the second stack, and the intermediate shunt stack can be implemented on, for example, a silicon-on-insulator die.

In some embodiments, the switching module can further include a control circuit configured to support operations of the first stack, the second stack, and the intermediate shunt stack. The control circuit can be implemented on the silicon-on-insulator die, or on another semiconductor die.

According to some implementations, the present disclosure relates to a wireless device that includes a transceiver, a power amplifier configured to amplify a signal, and an antenna configured to support transmission of the signal. The wireless device further includes a switching circuit implemented to route the signal from the power amplifier to the antenna. The switching circuit includes a first stack and a second stack arranged in series between a first node and a second node, and defining an intermediate node between the first stack and the second stack, with each stack including a respective number of transistors arranged in series. The switching circuit further includes a switchable shunt path having a first end and a second end, with the first end being coupled to the intermediate node such that the switchable shunt path is capable of connecting the intermediate node to the second end.

In some embodiments, the switching circuit can be configured such that when the signal being routed to the antenna passes through the first node to a third node, the first stack, the second stack, and the switchable shunt path are configured to isolate the second node from the first node.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 depicts a radio-frequency (RF) switch assembly having one or more features as described herein.

FIG. 2 depicts a switched path that can be implemented in the RF switch assembly of FIG. 1.

FIG. 3 shows that in some embodiments, a stack in the example of FIG. 2 can include a number of transistors arranged in series.

FIG. 4 shows an example of the switched path of FIG. 3, in which the quantities X and Y for the first and second stacks can be the same.

FIG. 5 shows another example of the switched path of FIG. 3, in which the quantities X and Y for the first and second stacks can be different.

FIGS. 6A. 6B and 6C show examples of how the first stack, the second stack, and the intermediate shunt stack of FIG. 3 can be operated to provide various functionalities for the switched path.

FIG. 7 shows a switch assembly that can be a more specific example of the switch assembly of FIG. 1.

FIG. 8 shows the switch assembly of FIG. 7 configured to support a low power operating mode involving the signal nodes TRX_HB and DRX_HB, and the antenna nodes TRX_HB_ANT1 and TRX_HB_ANT2.

FIG. 9 shows the switch assembly of FIG. 7 configured to support a high power operating mode involving the signal node TX_2GHB and the antenna node TRX_HB_ANT2.

FIG. 10 shows the switch assembly of FIG. 7 configured to support a high power operating mode involving the signal node MLB and the antenna node TRX_HB_ANT2.

FIG. 11 shows the switch assembly of FIG. 7 configured to support a low power operating mode involving the signal nodes DRX_HB and MLB and, and the antenna nodes TRX_HB_ANT2 and TRX_HB_ANT1.

FIG. 12 shows the switch assembly of FIG. 7 configured to support a high power operating mode involving the signal node TRX_HB and the antenna node TRX_HB_ANT2.

FIG. 13 shows the switch assembly of FIG. 7 configured to support a high power operating mode involving the signal node TX_2GHB and the antenna node TRX_HB_ANT1.

FIG. 14 shows the switch assembly of FIG. 7 configured to support a high power operating mode involving the signal node TX_2GHB and the antenna node TRX_HB_ANT1, similar to the example of FIG. 13.

FIG. 15 shows an example of a control functionality that can be provided for the example switch assembly of FIG. 7.

FIG. 16 shows another example of a control functionality that can be provided for the example switch assembly of FIG. 7.

FIG. 17 shows yet another example of a control functionality that can be provided for the example switch assembly of FIG. 7.

FIG. 18 shows that in some embodiments, a semiconductor die can include substantially all of a switch assembly having one or more features as described herein.

FIG. 19 shows that in some embodiments, a semiconductor die can include substantially all of a switch assembly, as well as some or all of a control component, as described herein.

FIG. 20 shows that in some embodiments, a packaged module can include a switch die such as a die of FIG. 18 or FIG. 19.

FIG. 21 shows that in some embodiments, a packaged module can include a switch die with or without a control component, and a separate die having a control circuit.

FIG. 22 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

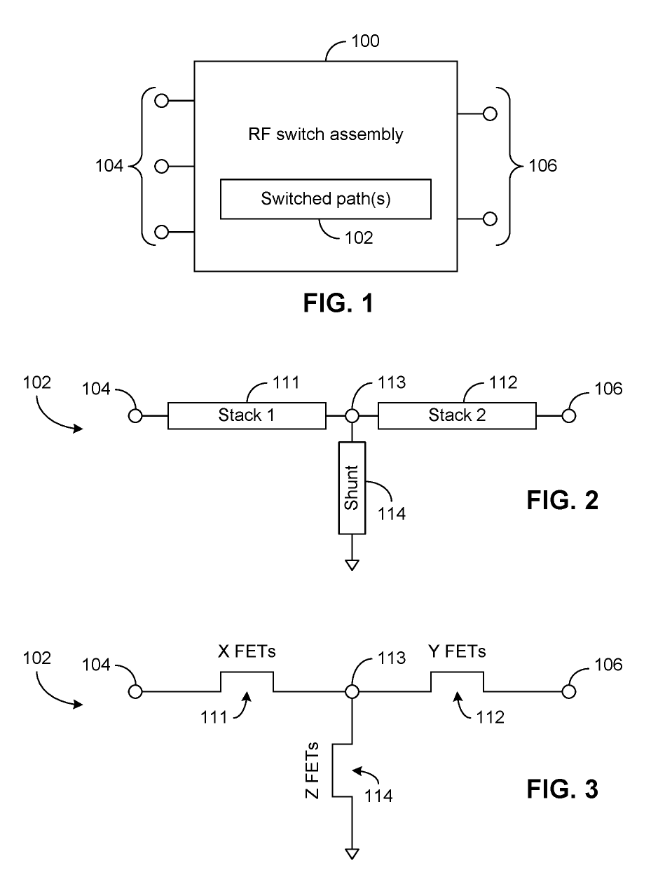

FIG. 1 depicts a radio-frequency (RF) switch assembly 100 having one or more features as described herein. In some embodiments, such an RF switch assembly can include one or more switched paths 102 configured to provide respective path(s) for signal(s) between a first set of one or more nodes (collectively indicated as 104) and a second set of one or more nodes (collectively indicated as 106). For example, the first set of one or more nodes 104 can be transmit (Tx) and/or receive (Rx) nodes in a front-end (FE) circuitry, and the second set of one or more nodes 106 can be antenna node(s) associated with one or more antennas.

FIG. 2 depicts a switched path 102 that can be implemented in the RF switch assembly 100 of FIG. 1. In FIG. 2, the switched path 102 is shown to include a signal path between a first node 104 and a second node 106. Such a signal path can include a first stack 111 in series with a second stack 112, with an intermediate node 113 between the two stacks 111, 112. An intermediate shunt stack 114 is shown to be implemented between the intermediate node 113 and a ground. Various examples related to the foregoing configuration of the switched path 102 are described herein in greater detail.

FIG. 3 shows that in some embodiments, each of the stacks 111, 112, 114 can include a number of transistors (e.g., field-effect transistors (FETs)) arranged in series. For example, the first stack 111 can include X FETs; the second stack 112 can include Y FETs; and the intermediate shunt stack 114 can include Z FETs. In some embodiments, the quantities X, Y and Z can be positive integers (e.g., greater than one), and may or may not have same values. In some embodiments, the quantities X and Y for the first and second stacks 111, 112 can be different.

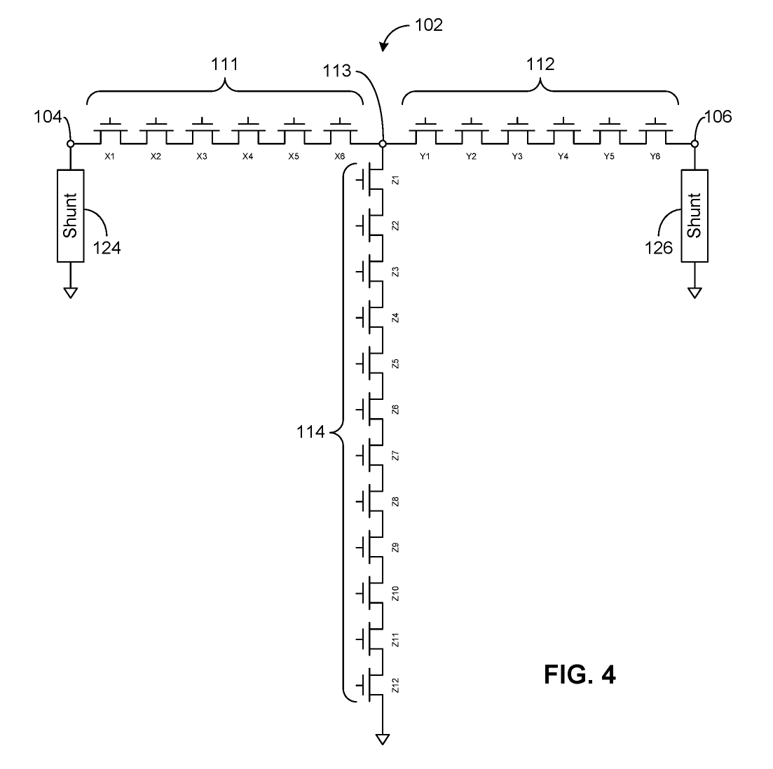

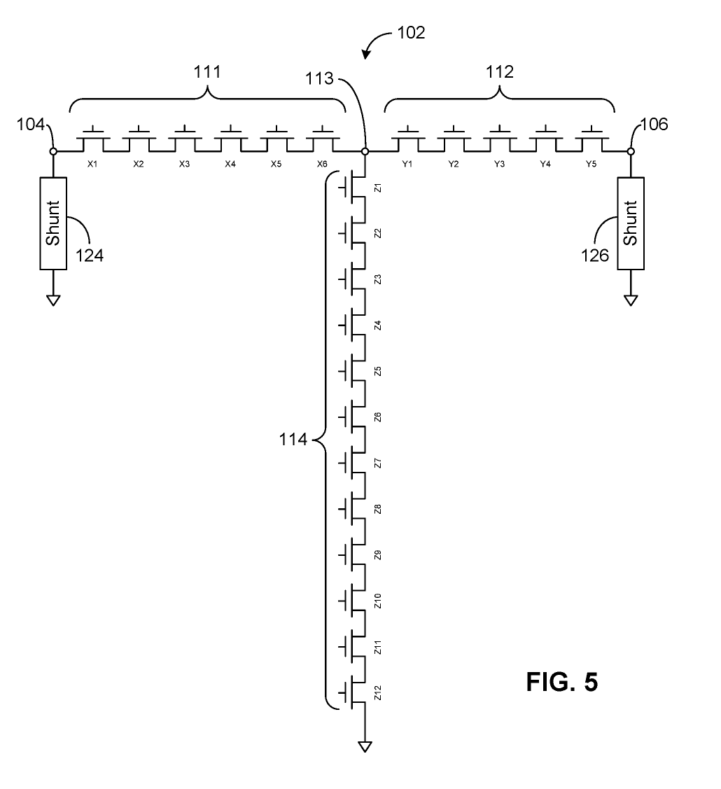

FIGS. 4 and 5 show more specific examples of the switched path 102 of FIG. 3, in which the quantities X and Y for the first and second stacks 111, 112 can be the same (FIG. 4) or be different (FIG. 5). For the purpose of description, and based on such numbers of FETs in the first and second stacks 111, 112, the example of FIG. 4 can be referred to as a symmetric configuration (X=Y), and the example of FIG. 5 can be referred to as an asymmetric configuration (X≠Y). It will be understood that symmetric and asymmetric configurations can also be based on one or more other properties of the FETs in the respective stacks.

In each of the examples of FIGS. 4 and 5, the intermediate shunt stack 114 is shown to include 12 FETs (Z1 to Z12) arranged in series between the intermediate node 113 and the ground. It will be understood that other numbers of FETs can be utilized for such an intermediate shunt stack. It will also be understood that the number of FETs in the symmetric configuration may or may not be the same as the number of FETs in the asymmetric configuration.

In some embodiments, the asymmetric configuration of FIG. 5 can allow a switched path to provide desired performance such as isolation and insertion loss without using unnecessary devices and related resources. For example, the side of a given switched path for receiving a power-amplified signal can be provided with more FETs in the respective stack than the stack on the other side of the switched path (relative to the corresponding intermediate shunt stack). In the context of the example of FIG. 5, the stack 111 with six FETs (between the first end node 104 and the intermediate node 113) can be provided such that the first end node 104 receives a power-amplified signal. With such a configuration, the five FETs (between the intermediate node 113 and the second end node 106) can be provided such that the second end node 106 is, for example, an antenna node.

In the foregoing example, the first stack 111 can include, for example, six 4.56 μm FETs, and the second stack 112 can include, for example, five 4.56 μm FETs. The intermediate shunt stack 114 can include, for example, twelve 0.8 μm FETs. It will be understood that FETs in the first stack 111, the second stack 112, and the intermediate shunt stack 114 can include different numbers of FETs and/or different sized FETs.

In some embodiments, and as shown in each of the examples of FIGS. 4 and 5, an end shunt path can be provided from each of the first and second end nodes 104, 106 of the switched path 102. More particularly, an end shunt path 124 can provide a switchable shunt path to ground from the first end node 104, and an end shunt path 126 can provide a switchable shunt path to ground from the second end node 106. In some embodiments, each of such end shunt paths can include a stack of FETs arranged in series. In some embodiments, it will be understood that either or both of such end shunt paths may be absent.

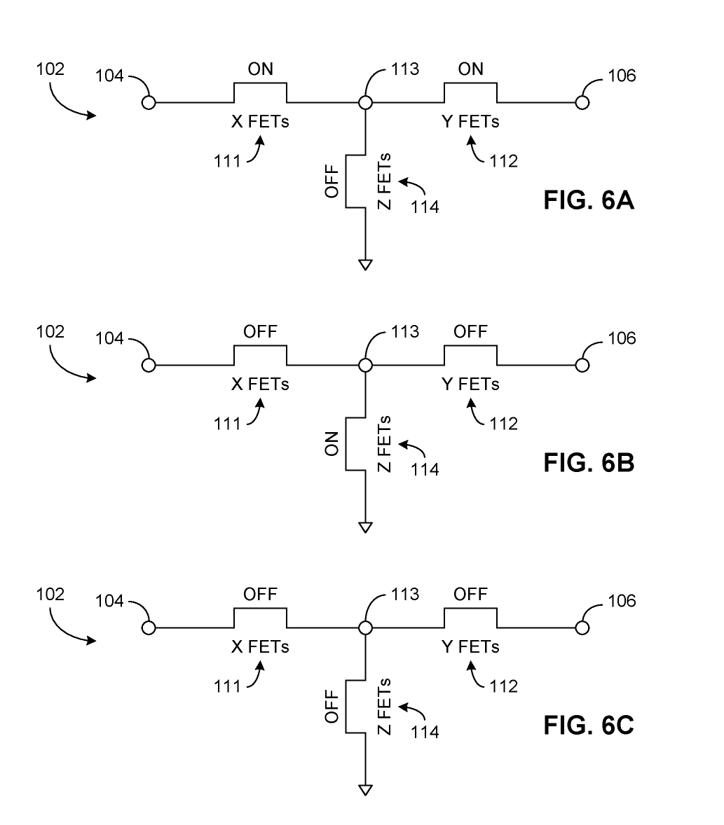

FIGS. 6A-6C show examples of how the first stack 111, the second stack 112, and the intermediate shunt stack 114 of FIG. 3 can be operated to provide various functionalities for the switched path 102. For example, and as shown in FIG. 6A, the first and second end nodes 104, 106 can be connected to allow passage of a signal therebetween, by turning each of the first and second stacks 111, 112 ON, and turning the intermediate shunt stack 114 OFF.

In another example, and as shown in FIG. 6B, the first and second end nodes 104, 106 can be disconnected to provide isolation therebetween, by turning each of the first and second stacks 111, 112 OFF, and turning the intermediate shunt stack 114 ON. In such a mode, the stack on the signal input side can be configured to handle the power of the signal. For example, and in the context of the example of FIG. 5, suppose that the signal is provided to the first end node 104. With the operating configuration of FIG. 6B, the first stack 111 of six FETs (X1 to X6), as well as the second stack 112 of five FETs (Y1 to Y5) are turned OFF, and the intermediate shunt stack 114 of twelve FETs (Z1 to Z12) is turned ON. Accordingly, the first stack 111 of six FETs (X1 to X6) can handle the power of the signal (if present at the first end node 104) before being shunted to ground by the intermediate shunt stack 114 (if any power is present at the intermediate node 113). In some embodiments, such a power handling stack (e.g., the first stack 111 in the foregoing example) can be configured to be suitable for, for example, operating conditions where the signal has lower power.

In another example, and as shown in FIG. 6C, the first and second end nodes 104, 106 can be disconnected to provide isolation therebetween, by turning each of the first and second stacks 111, 112 OFF, and also turning the intermediate shunt stack 114 OFF. In such a mode, the stacks on the signal input side and the signal output side (relative to the intermediate node 113) can be combined to handle the power of the signal, since the intermediate shunt stack 114 is OFF. For example, and in the context of the example of FIG. 5, suppose that the signal is provided to the first end node 104. With the operating configuration of FIG. 6C, the first stack 111 of six FETs (X1 to X6), as well as the second stack 112 of five FETs (Y1 to Y5) are turned OFF, and the intermediate shunt stack 114 of twelve FETs (Z1 to Z12) is turned OFF. Accordingly, the first stack 111 of six FETs (X1 to X6) and the second stack 112 of five FETs (Y1 to Y5) together can handle the power of the signal (if present at the first end node 104), since the intermediate shunt stack 114 is OFF. In some embodiments, such a power handling stack combination (e.g., the first and second stacks 111, 112 in the foregoing example) can be configured to be suitable for, for example, operating conditions where the signal has higher power.

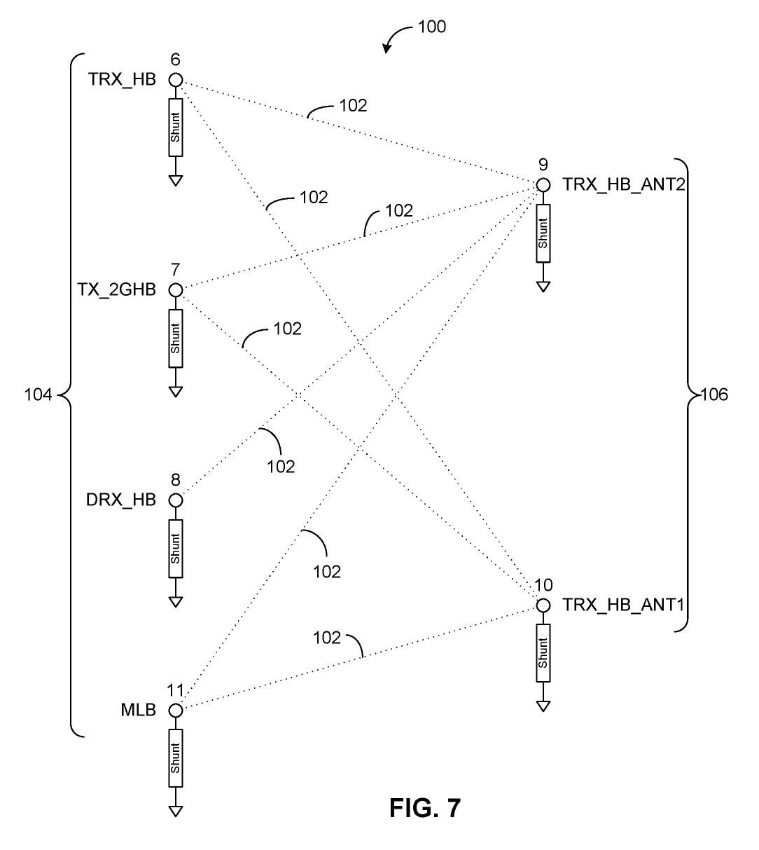

FIG. 7 shows a switch assembly 100 that can be a more specific example of the switch assembly 100 of FIG. 1. In the example of FIG. 7, such a switch assembly is shown to include a plurality of first nodes 104, and a plurality of second nodes 106. More particularly, the first nodes are shown to include four example signal nodes TRX_HB for transmit (Tx) and receive (Rx) operations in high-band (HB), TX_2GHB for Tx operation in 2G HB, DRX_HB for diversity Rx operation in HB, and MLB for Tx and/or Rx operations in mid-band (MB) and low-band (LB).

In the example of FIG. 7, the second nodes 106 of the switch assembly 100 is shown to include two example antenna nodes to accommodate variations with the foregoing signal nodes 104. More particularly, an antenna node TRX_HB_ANT1 can be provided as a first antenna to support Tx and Rx operations in at least HB, and an antenna TRX_HB_ANT2 can be provided as a second antenna to support Tx and Rx operations in at least HB.

In the example of FIG. 7, a switchable shunt path to ground is shown to be provided for each of the signal nodes 104 and the antenna nodes 106. It will be understood that in some embodiments, such a switchable shunt path may or may not be implemented for a given node.

With the example signal nodes 104 and the antenna nodes 106 in FIG. 7, various switched signal paths 102 can be implemented. In some embodiments, some or all of such switched signal paths 102 can be configured to include one or more features as described herein. For example, some of all of such switched signal paths 102 can include respective intermediate shunt stack(s) (e.g., 114 in FIG. 3), and each of the switched signal path(s) 102 having the intermediate shunt stack can have a symmetric configuration or an asymmetric configuration.

It will be understood that the four signal nodes 104 and the two antenna nodes 106 are examples, and one or more features of the present disclosure can be implemented with other numbers of signal nodes and other numbers of antenna nodes. It will also be understood that one or more features of the present disclosure can be implemented for combinations of bands other than those shown in the example of FIG. 7.

In the example of FIG. 7, the signal nodes 104 and the antenna nodes 106 are shown with numbers as listed in Table 1. Such node numbers are to indicate various signal paths that can be formed between the signal nodes 104 and the antenna nodes 106. For example, a switched signal path between nodes 6 and 9 is referred to herein as a path 6-9.

TABLE 1

| Node name: | Node number |
|---|---|
| TRX_HB | 6 |
| TX_2GHB | 7 |
| DRX_HB | 8 |
| MLB | 11 |
| TRX_HB_ANT1 | 10 |
| TRX_HB_ANT2 | 9 |

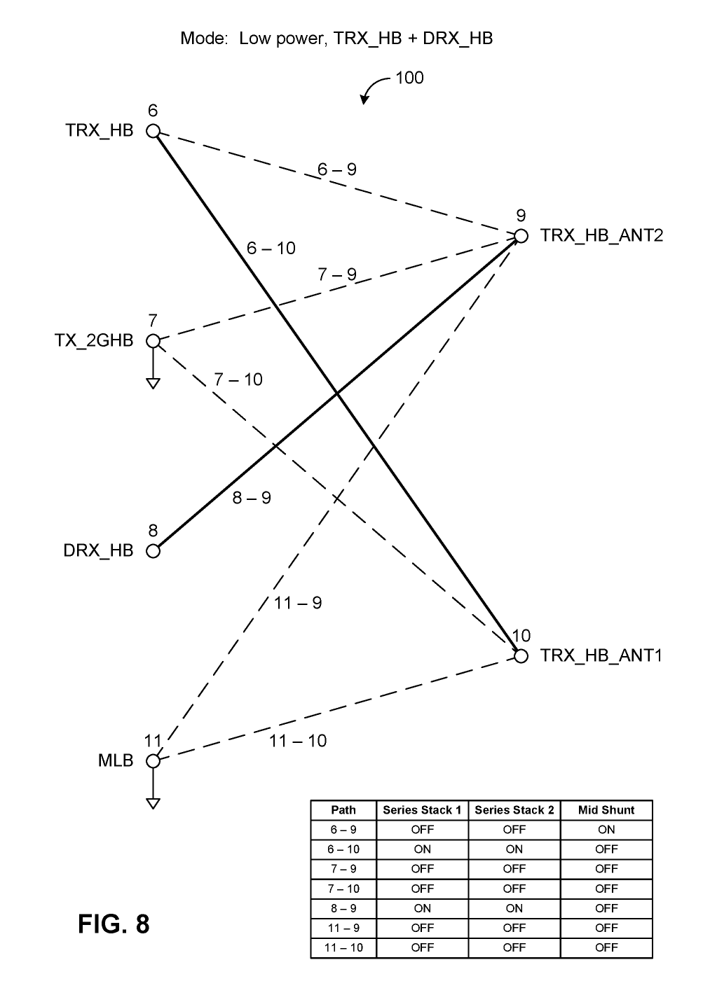

FIGS. 8-14 show non-limiting examples of how the switch assembly 100 of FIG. 7 can be operated to provide various operating modes. In the examples of FIGS. 8-14, an enabled signal path for conducting a signal between the respective nodes is depicted by a solid line, and a disabled signal path between the respective nodes is depicted by a dashed line.

For example, FIG. 8 shows the switch assembly 100 configured to support a low power operating mode involving the signal nodes TRX_HB (6) and DRX_HB (8), and the antenna nodes TRX_HB_ANT1 (10) and TRX_HB_ANT2 (9). Accordingly, an enabled signal path 6-10 can be provided between the signal node TRX_HB (6) and the antenna node TRX_HB_ANT1 (10), and an enabled signal path 8-9 can be provided between the signal node DRX_HB (8) and the antenna node TRX_HB_ANT2 (9). The enabled signal path 6-10 can support, for example, duplex operations involving a received signal (at node 10) and a low power transmit signal (at node 6). The enabled signal path 8-9 can support, for example, a diversity receive operation involving a received signal (at node 9). Other signal paths in the switch assembly 100 can be disabled as shown in FIG. 8.

FIG. 8 also shows an example of how the various switched paths, including the enabled signal paths 6-10 and 8-9, can be operated. For the enabled signal paths 6-10 and 8-9, each of the first and second series stacks (111 and 112 in FIG. 3) can be turned ON, and the corresponding intermediate shunt stack (114 in FIG. 3) can be turned OFF.

For the switched path 6-9 that shares the signal node 6 with the foregoing enabled signal path 6-10, it is desired to provide an appropriate isolation between the respective nodes 6 and 9 due to the presence of the low power transmit signal at node 6. Thus, both of the first and second series stacks of the switched path 6-9 can be turned OFF. Since the transmit signal at node 6 (being routed to node 10) is a low power signal, the intermediate shunt path of the switched path 6-9 can be turned ON, and the corresponding first series stack (111 in FIG. 3) can handle the power of the signal at node 6.

In the example of FIG. 8, each of the disabled switched paths that does not share an active transmit signal node (e.g., node 6) can be turned OFF. In such an OFF configuration, each of the first and second series stacks, and the intermediate shunt stack can be turned OFF.

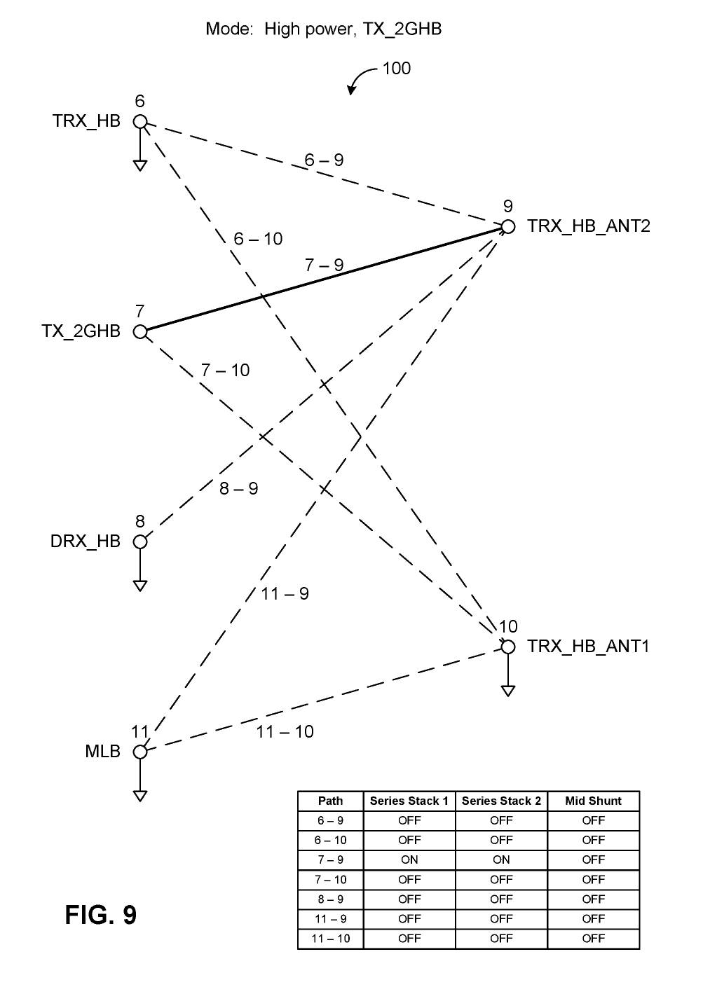

In another example, FIG. 9 shows the switch assembly 100 configured to support a high power operating mode involving the signal node TX_2GHB (7) and the antenna node TRX_HB_ANT2 (9). Accordingly, an enabled signal path 7-9 can be provided between the signal node TX_2GHB (7) and the antenna node TRX_HB_ANT2 (9). The enabled signal path 7-9 can support, for example, a transmit operation involving a high power transmit signal (at node 7). Other signal paths in the switch assembly 100 can be disabled as shown in FIG. 9.

FIG. 9 also shows an example of how the various switched paths, including the enabled signal path 7-9, can be operated. For the enabled signal path 7-9, each of the first and second series stacks (111 and 112 in FIG. 3) can be turned ON, and the corresponding intermediate shunt stack (114 in FIG. 3) can be turned OFF.

For the switched path 7-10 that shares the signal node 7 with the foregoing enabled signal path 7-9, it is desired to provide an appropriate isolation between the respective nodes 7 and 10 due to the presence of the high power transmit signal at node 7. Thus, both of the first and second series stacks of the switched path 7-10 can be turned OFF. Since the transmit signal at node 7 (being routed to node 9) is a high power signal, the intermediate shunt path of the switched path 7-10 can be turned OFF, and both of the corresponding first and second series stacks (111, 112 in FIG. 3) can handle the power of the signal at node 7.

In the example of FIG. 9, each of the disabled switched paths that does not share an active transmit signal node (e.g., node 7) can be turned OFF. In such an OFF configuration, each of the first and second series stacks, and the intermediate shunt stack can be turned OFF.

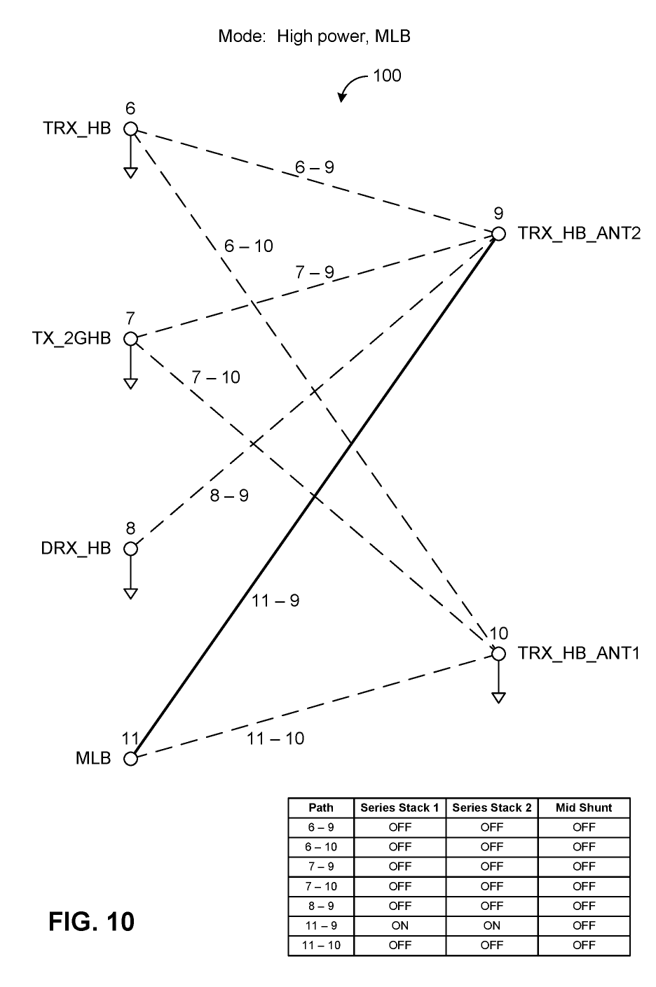

In yet another example, FIG. 10 shows the switch assembly 100 configured to support a high power operating mode involving the signal node MLB (11) and the antenna node TRX_HB_ANT2 (9). Accordingly, an enabled signal path 11-9 can be provided between the signal node MLB (11) and the antenna node TRX_HB_ANT2 (9). The enabled signal path 11-9 can support, for example, duplex operations involving a received signal (at node 9) and a high power transmit signal (at node 11). Other signal paths in the switch assembly 100 can be disabled as shown in FIG. 10.

FIG. 10 also shows an example of how the various switched paths, including the enabled signal path 11-9, can be operated. For the enabled signal path 11-9, each of the first and second series stacks (111 and 112 in FIG. 3) can be turned ON, and the corresponding intermediate shunt stack (114 in FIG. 3) can be turned OFF.

For the switched path 11-10 that shares the signal node 11 with the foregoing enabled signal path 11-9, it is desired to provide an appropriate isolation between the respective nodes 11 and 10 due to the presence of the high power transmit signal at node 11. Thus, both of the first and second series stacks of the switched path 11-10 can be turned OFF. Since the transmit signal at node 11 (being routed to node 9) is a high power signal, the intermediate shunt path of the switched path 11-10 can be turned OFF, and both of the corresponding first and second series stacks (111, 112 in FIG. 3) can handle the power of the signal at node 11.

In the example of FIG. 10, each of the disabled switched paths that does not share an active transmit signal node (e.g., node 11) can be turned OFF. In such an OFF configuration, each of the first and second series stacks, and the intermediate shunt stack can be turned OFF.

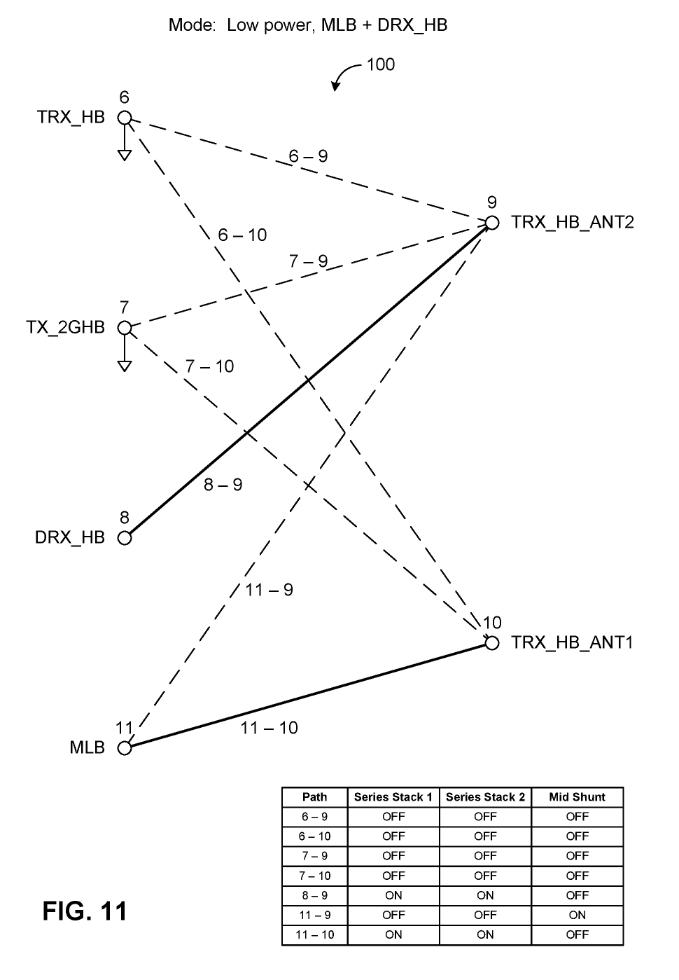

In yet another example, FIG. 11 shows the switch assembly 100 configured to support a low power operating mode involving the signal nodes DRX_HB (8) and MLB (11), and the antenna nodes TRX_HB_ANT2 (9) and TRX_HB_ANT1 (10). Accordingly, an enabled signal path 8-9 can be provided between the signal node DRX_HB (8) and the antenna node TRX_HB_ANT2 (9), and an enabled signal path 11-10 can be provided between the signal node MLB (11) and the antenna node TRX_HB_ANT1 (10). The enabled signal path 8-9 can support, for example, a diversity receive operation involving a received signal (at node 9). The enabled signal path 11-10 can support, for example, duplex operations involving a received signal (at node 10) and a low power transmit signal (at node 11). Other signal paths in the switch assembly 100 can be disabled as shown in FIG. 11.

FIG. 11 also shows an example of how the various switched paths, including the enabled signal paths 8-9 and 11-10, can be operated. For the enabled signal paths 8-9 and 11-10, each of the first and second series stacks (111 and 112 in FIG. 3) can be turned ON, and the corresponding intermediate shunt stack (114 in FIG. 3) can be turned OFF.

For the switched path 11-9 that shares the signal node 11 with the foregoing enabled signal path 11-10, it is desired to provide an appropriate isolation between the respective nodes 11 and 9 due to the presence of the low power transmit signal at node 11. Thus, both of the first and second series stacks of the switched path 11-9 can be turned OFF. Since the transmit signal at node 11 (being routed to node 10) is a low power signal, the intermediate shunt path of the switched path 11-9 can be turned ON, and the corresponding first series stack (111 in FIG. 3) can handle the power of the signal at node 11.

In the example of FIG. 11, each of the disabled switched paths that does not share an active transmit signal node (e.g., node 11) can be turned OFF. In such an OFF configuration, each of the first and second series stacks, and the intermediate shunt stack can be turned OFF.

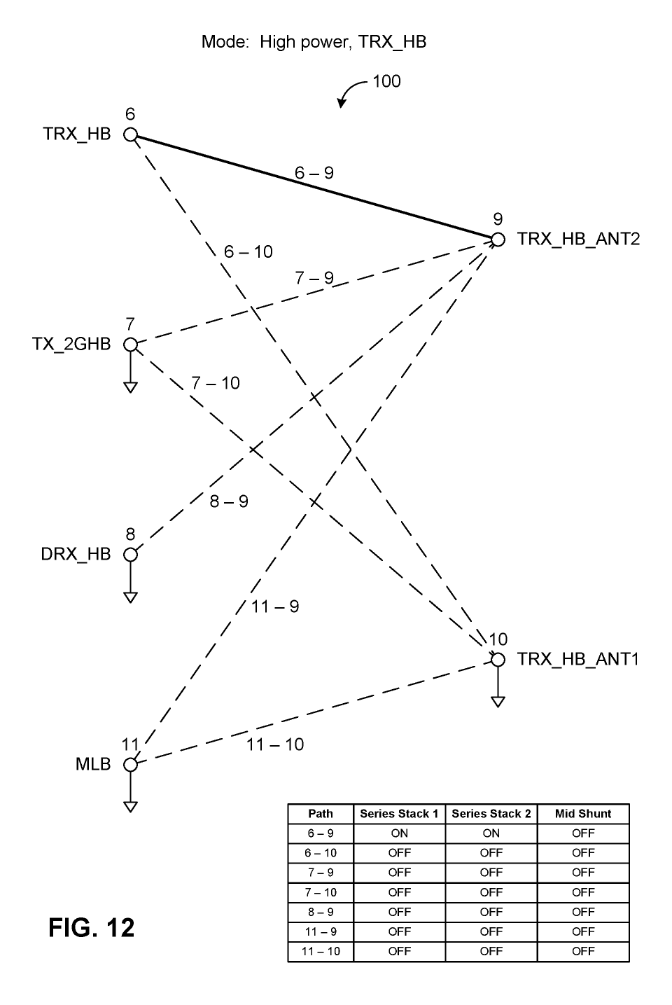

In yet another example, FIG. 12 shows the switch assembly 100 configured to support a high power operating mode involving the signal node TRX_HB (6) and the antenna node TRX_HB_ANT2 (9). Accordingly, an enabled signal path 6-9 can be provided between the signal node TRX_HB (6) and the antenna node TRX_HB_ANT2 (9). The enabled signal path 6-9 can support, for example, duplex operations involving a received signal (at node 9) and a high power transmit signal (at node 6). Other signal paths in the switch assembly 100 can be disabled as shown in FIG. 12.

FIG. 12 also shows an example of how the various switched paths, including the enabled signal path 6-9, can be operated. For the enabled signal path 6-9, each of the first and second series stacks (111 and 112 in FIG. 3) can be turned ON, and the corresponding intermediate shunt stack (114 in FIG. 3) can be turned OFF.

For the switched path 6-10 that shares the signal node 6 with the foregoing enabled signal path 6-9, it is desired to provide an appropriate isolation between the respective nodes 6 and 10 due to the presence of the high power transmit signal at node 6. Thus, both of the first and second series stacks of the switched path 6-10 can be turned OFF. Since the transmit signal at node 6 (being routed to node 9) is a high power signal, the intermediate shunt path of the switched path 6-10 can be turned OFF, and both of the corresponding first and second series stacks (111, 112 in FIG. 3) can handle the power of the signal at node 6.

In the example of FIG. 12, each of the disabled switched paths that does not share an active transmit signal node (e.g., node 6) can be turned OFF. In such an OFF configuration, each of the first and second series stacks, and the intermediate shunt stack can be turned OFF.

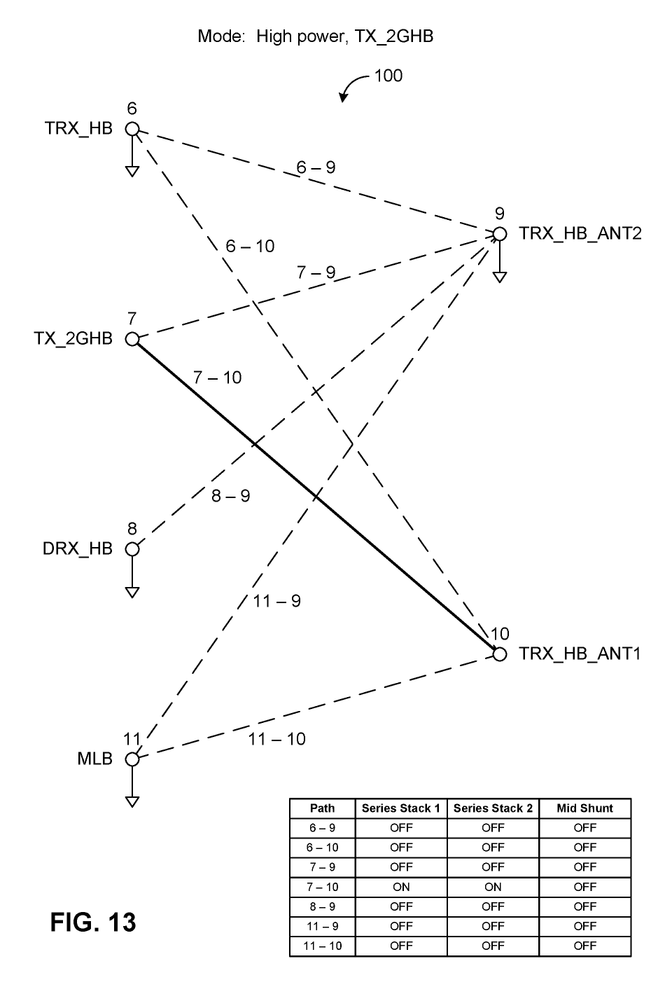

In yet another example, FIG. 13 shows the switch assembly 100 configured to support a high power operating mode involving the signal node TX_2GHB (7) and the antenna node TRX_HB_ANT1 (10). Accordingly, an enabled signal path 7-10 can be provided between the signal node TX_2GHB (7) and the antenna node TRX_HB_ANT1 (10). The enabled signal path 7-10 can support, for example, a transmit operation involving a high power transmit signal (at node 7). Other signal paths in the switch assembly 100 can be disabled as shown in FIG. 13.

FIG. 13 also shows an example of how the various switched paths, including the enabled signal path 7-10, can be operated. For the enabled signal path 7-10, each of the first and second series stacks (111 and 112 in FIG. 3) can be turned ON, and the corresponding intermediate shunt stack (114 in FIG. 3) can be turned OFF.

For the switched path 7-9 that shares the signal node 7 with the foregoing enabled signal path 7-10, it is desired to provide an appropriate isolation between the respective nodes 7 and 9 due to the presence of the high power transmit signal at node 7. Thus, both of the first and second series stacks of the switched path 7-9 can be turned OFF. Since the transmit signal at node 7 (being routed to node 10) is a high power signal, the intermediate shunt path of the switched path 7-9 can be turned OFF, and both of the corresponding first and second series stacks (111, 112 in FIG. 3) can handle the power of the signal at node 7.

In the example of FIG. 13, each of the disabled switched paths that does not share an active transmit signal node (e.g., node 7) can be turned OFF. In such an OFF configuration, each of the first and second series stacks, and the intermediate shunt stack can be turned OFF.

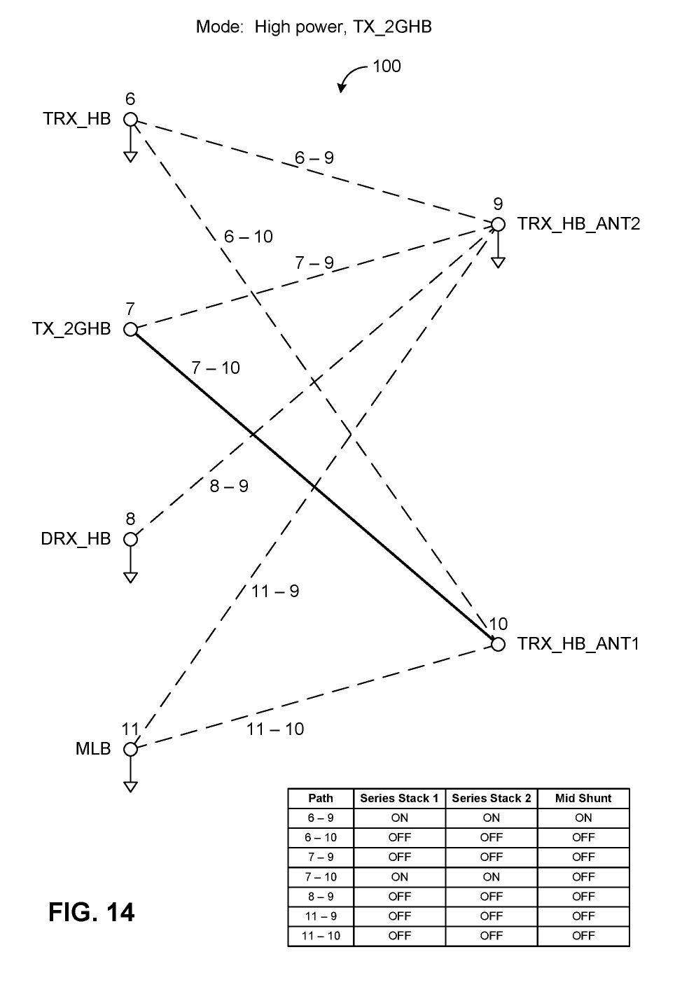

FIG. 14 shows the switch assembly 100 configured to support a high power operating mode involving the signal node TX_2GHB (7) and the antenna node TRX_HB_ANT1 (10), similar to the example of FIG. 13. In the example of FIG. 14, however, it may be desirable to provide additional isolation for the enabled signal path 7-10 from, for example, another HB transmit path. Thus, and as shown in the table of FIG. 14, each of the first series stack (111 in FIG. 3), the second series stack (112 in FIG. 3), and the intermediate shunt stack (114 in FIG. 3) of the switched path 6-9 (which is associated with the TRX_HB node (6)) can be turned ON. In such a configuration, additional shunting functionality can be provided by the intermediate shunt stack of the switched path 6-9. In some embodiments, the foregoing configuration of the switched path 6-9 can be achieved by, for example, an additional control line for the intermediate shunt stack.

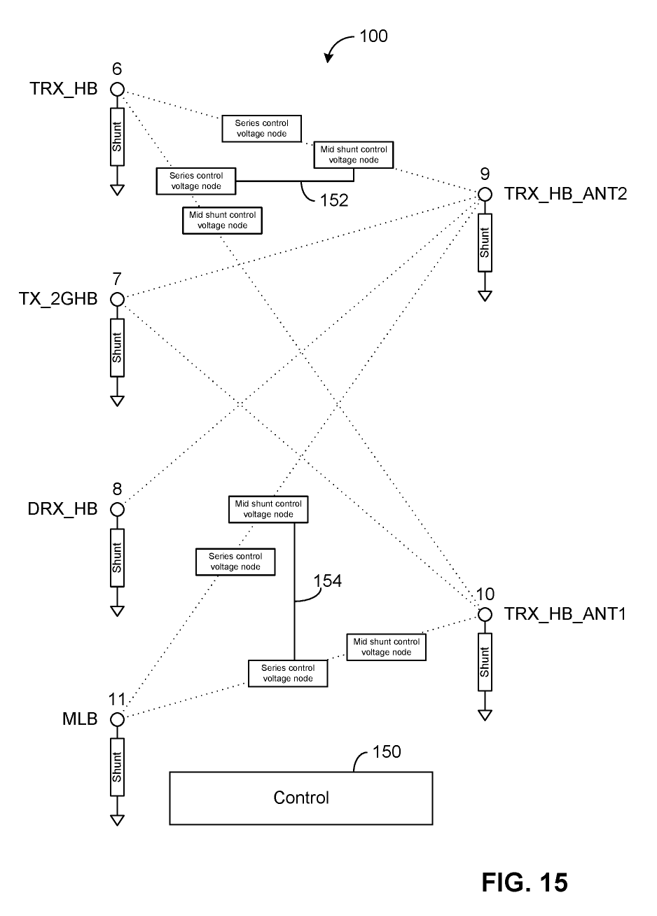

FIGS. 15-17 show examples of how the switch assembly 100 of FIGS. 7-14 can be controlled to provide various switching functionalities. FIG. 15 shows that in some embodiments, a control component 150 can be provided for the switch assembly 100, and such a control component can generate or support a common control signal that can be provided to a series portion (e.g., the first and second series stacks) of a first switched path, and also to a shunt portion (e.g., the intermediate shunt stack) of a second switched path that shares a signal node with the first switched path.

For example, the series portion of the switched path 6-10 and the shunt portion of the switched path 6-9 (sharing the signal node 6) can be controlled by a common control signal (indicated as 152). In the context of the operating mode examples of FIGS. 7-14, the foregoing control scheme can be utilized in the example of FIG. 12, where the series portion of the switched path 6-10 is turned OFF, and the shunt portion of the switched path 6-9 is also turned OFF.

In another example, the series portion of the switched path 11-10 and the shunt portion of the switched path 11-9 (sharing the signal node 11) can be controlled by a common control signal (indicated as 154). In the context of the operating mode examples of FIGS. 7-14, the foregoing control scheme can be utilized in the examples of FIGS. 10 and 11, where the series portion of the switched path 11-10 is turned OFF (in FIG. 10) or ON (in FIG. 11), and the shunt portion of the switched path 11-9 is also turned OFF (in FIG. 10) or ON (in FIG. 11).

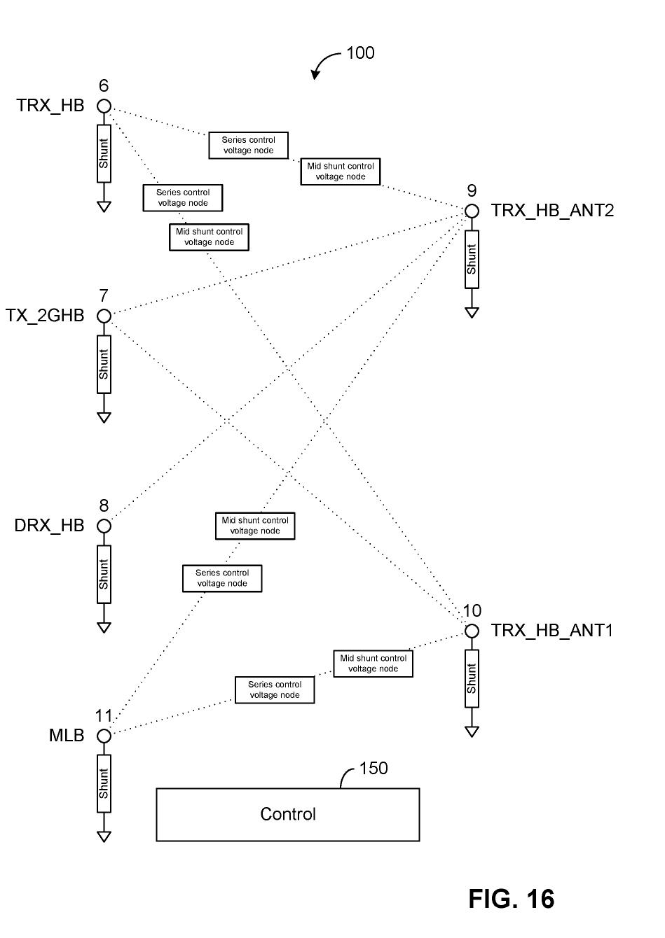

FIG. 16 shows that in some embodiments, a control component 150 can be provided for the switch assembly 100, and such a control component can generate or support an independent control signal that can be provided to each of a series portion (e.g., the first and second series stacks) of a first switched path, and a shunt portion (e.g., the intermediate shunt stack) of a second switched path that shares a signal node with the first switched path.

For example, each of the series portion of the switched path 6-10 and the shunt portion of the switched path 6-9 (sharing the signal node 6) can be controlled by a separate control signal. In another example, each of the series portion of the switched path 11-10 and the shunt portion of the switched path 11-9 (sharing the signal node 11) can be controlled by a separate control signal. In the context of the operating mode examples of FIGS. 7-14, the foregoing control scheme of independent control can be utilized in the example of FIG. 14, where the shunt portion of the switched path 6-9 can be turned ON independent of the state of the series portion of the switched path 6-10 (which is OFF in FIG. 14).

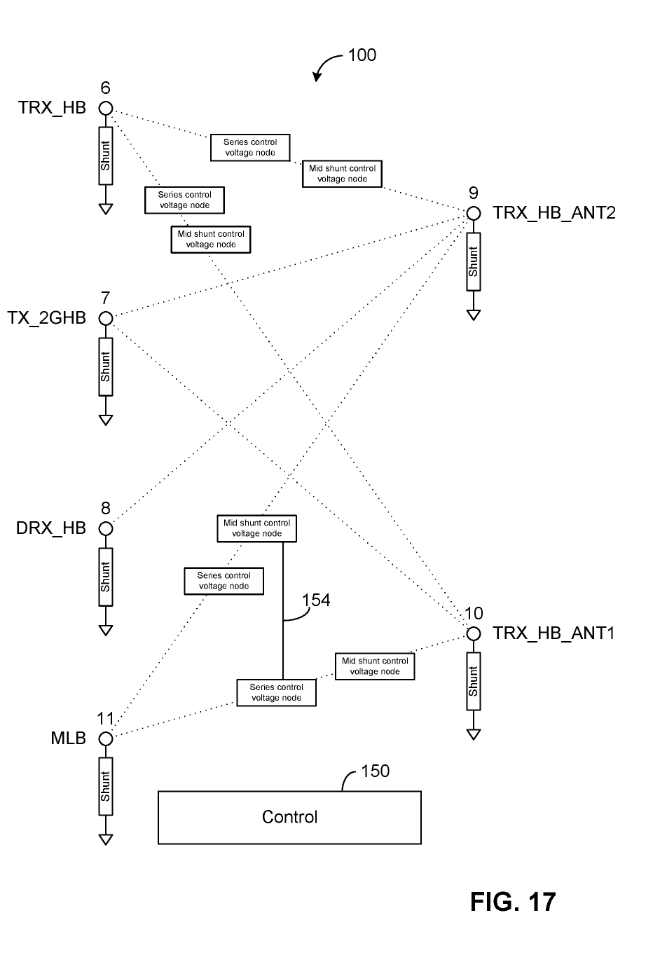

FIG. 17 shows that in some embodiments, a control component 150 can be provided for the switch assembly 100, and such a control component can be configured to provide a control functionality that is some combination of the control functionalities of FIGS. 15 and 16. For example, each of the series portion of the switched path 6-10 and the shunt portion of the switched path 6-9 (sharing the signal node 6) can be controlled by a separate control signal; and the series portion of the switched path 11-10 and the shunt portion of the switched path 11-9 (sharing the signal node 11) can be controlled by a common control signal (indicated as 154).

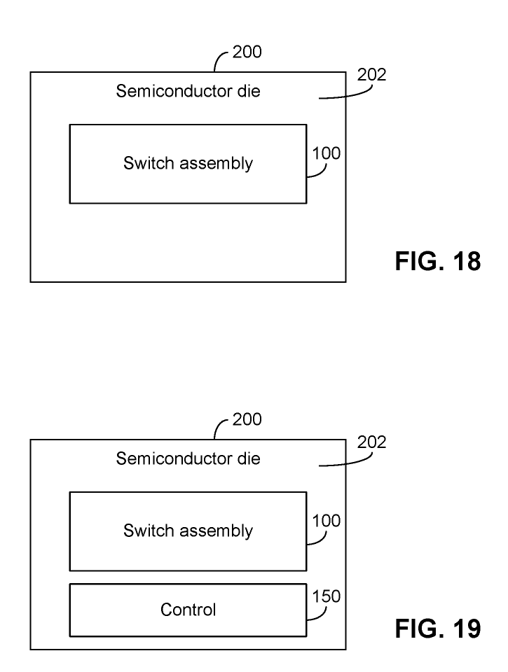

FIGS. 18-22 show various products that can utilize a switch assembly having one or more features as described herein. For example, FIGS. 18 and 19 show that in some embodiments, a switch assembly 100 having one or more features as described herein can be implemented on a substrate 202 of a semiconductor die 200. FIG. 18 shows that in some embodiments, the semiconductor die 200 can include substantially all of the switch devices associated with the switch assembly 100. FIG. 19 shows that in some embodiments, the semiconductor die 200 can include substantially all of the switch devices associated with the switch assembly 100, as well as some or all of the control component 150 as described herein (e.g., FIGS. 15-17).

In some embodiments, the semiconductor die 200 in the examples of FIGS. 18 and 19 can include, for example, a silicon-on-insulator (SOI) die. It will be understood that one or more features of the present disclosure can also be implemented with other types of semiconductor process technologies.

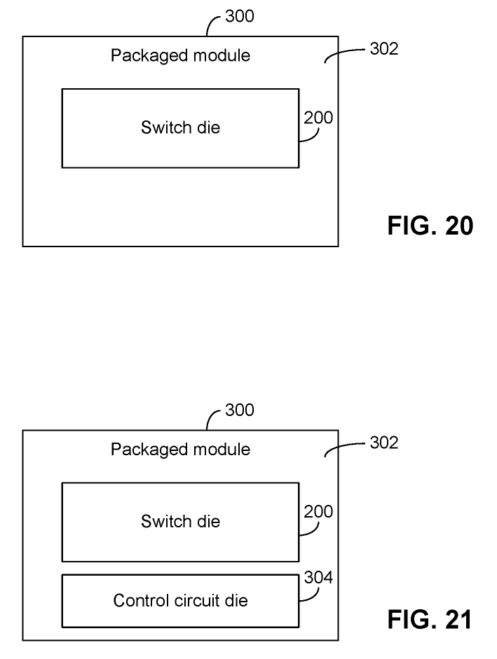

In another example, FIGS. 20 and 21 show that in some embodiments, a switch assembly 100 having one or more features as described herein can be a part of a packaged module 300. Such a packaged module can include a packaging substrate 302 configured to receive a plurality of components, and can be implemented as, for example, a laminate substrate, a ceramic substrate, etc. Such a packaged module can also include various connection features to allow mounting of the various components, as well as to allow various electrical connections associated with such components. Such a packaged module can also include an overmold structure that generally encapsulates some or all of the components on the packaging substrate 302. In some embodiments, the packaged module 300 can include one or more shielding features to provide RF shielding functionalities.

FIG. 20 shows that in some embodiments, the packaged module 300 can include a switch die 200, such as the die in the examples of FIGS. 18 and 19, mounted on the packaging substrate 302. FIG. 21 shows that in some embodiments, the packaged module 300 can include a switch die 200 with or without a control component, and a separate die 304 having a control circuit. Such a control circuit die can be configured to provide some or all of control functionalities associated with the switch die 200.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

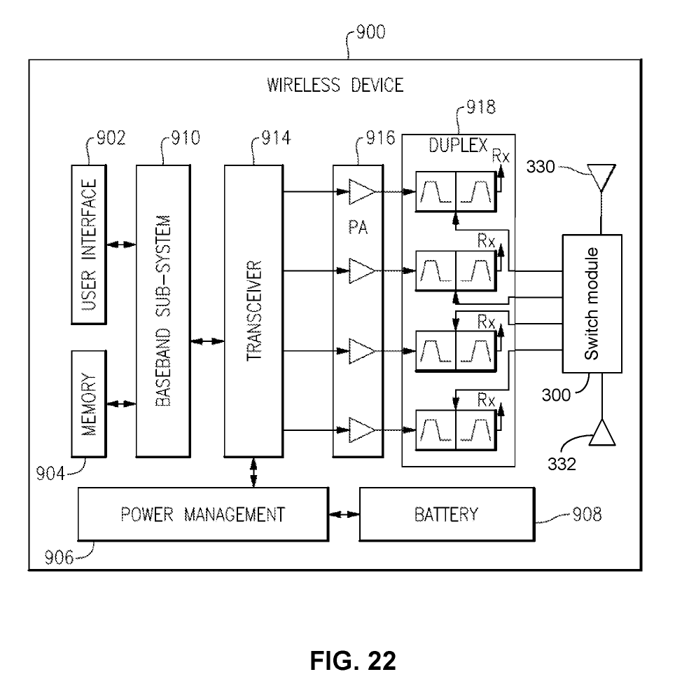

FIG. 22 depicts an example wireless device 900 having one or more advantageous features described herein. In the context of various switches as described herein, a switch assembly and its control component can be part of, for example, a switch module 300. In some embodiments, such a switch module can support, for example, various operating modes of the wireless device 900.

In the example wireless device 900, a power amplifier (PA) assembly 916 having a plurality of PAs can provide one or more amplified RF signals to the switch module 300 (via an assembly of one or more duplexers 918), and the switch module 300 can route the amplified RF signal(s) to one or more antennas. The PAs 916 can receive corresponding unamplified RF signal(s) from a transceiver 914 that can be configured and operated in known manners. The transceiver 914 can also be configured to process received signals. The transceiver 914 is shown to interact with a baseband sub-system 910 that is configured to provide conversion between data and/or voice signals suitable for a user and RF signals suitable for the transceiver 914. The transceiver 914 is also shown to be connected to a power management component 906 that is configured to manage power for the operation of the wireless device 900. Such a power management component can also control operations of the baseband sub-system 910 and the module 910.

The baseband sub-system 910 is shown to be connected to a user interface 902 to support various input and output of voice and/or data provided to and received from the user. The baseband sub-system 910 can also be connected to a memory 904 that is configured to store data and/or instructions to support the operation of the wireless device, and/or to provide storage of information for the user.

In some embodiments, the duplexers 918 can allow transmit and receive operations to be performed simultaneously using a common antenna (e.g., 924). In FIG. 22, received signals are shown to be routed to “Rx” paths that can include, for example, one or more low-noise amplifiers (LNAs).

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A switch assembly comprising:
a first stack and a second stack arranged in series between a first node and a second node, and defining an intermediate node between the first stack and the second stack, each stack including a respective number of transistors arranged in series; and
a switchable shunt path having a first end and a second end, the first end coupled to the intermediate node such that the switchable shunt path is capable of connecting the intermediate node to the second end.

2. The switch assembly of claim 1 wherein the second end of the switchable shunt path is configured to be coupled to a ground node.

3. The switch assembly of claim 2 wherein the switchable shunt path includes an intermediate shunt stack having a number of transistors arranged in series between the first end and the second end.

4. The switch assembly of claim 3 wherein the transistors in each of the first stack, the second stack, and the intermediate shunt stack are field-effect transistors such that sources and drains of the field-effect transistors form the series arrangement of the respective stack.

5. (canceled)

6. (canceled)

7. The switch assembly of claim 4 wherein the field-effect transistors of the first stack, the second stack, and the intermediate shunt stack are implemented as silicon-on-insulator devices.

8. The switch assembly of claim 4 wherein the number of transistors in the first stack is different than the number of transistors in the second stack.

9. The switch assembly of claim 8 wherein the first node is configured to receive a power-amplified signal for transmission, and the second node is configured to be connected to an antenna for transmission of the power-amplified signal.

10. The switch assembly of claim 9 wherein the number of transistors in the first stack is greater than the number of transistors in the second stack.

11. The switch assembly of claim 10 wherein the number of transistors in the first stack is selected to handle a power of the power-amplified signal present at the first node when each of the first and second stacks is turned off to disconnect the second node from the first node and the intermediate shunt stack is turned on.

12. (canceled)

13. The switch assembly of claim 10 wherein the number of transistors in the first stack and the number of transistors in the second stack are selected to handle a power of the power-amplified signal present at the first node when each of the first and second stacks is turned off to disconnect the second node from the first node and the intermediate shunt stack is turned off.

14. (canceled)

15. A switch die comprising:
a semiconductor substrate configured to allow formation of an integrated circuit; and
a switching circuit implemented on the substrate and including a first stack and a second stack arranged in series between a first node and a second node, and defining an intermediate node between the first stack and the second stack, each stack including a respective number of transistors arranged in series, the switching circuit further including a switchable shunt path having a first end and a second end, the first end coupled to the intermediate node such that the switchable shunt path is capable of connecting the intermediate node to the second end.

16. The switch die of claim 15 wherein the second end of the switchable shunt path is configured to be coupled to a ground node.

17. The switch die of claim 16 wherein the switchable shunt path includes an intermediate shunt stack having a number of transistors arranged in series between the first end and the second end.

18. The switch die of claim 17 wherein the transistors in each of the first stack, the second stack, and the intermediate shunt stack are field-effect transistors such that sources and drains of the field-effect transistors form the series arrangement of the respective stack.

19. The switch die of claim 18 wherein the field-effect transistors of the first stack, the second stack, and the intermediate shunt stack are implemented as silicon-on-insulator devices.

20. The switch die of claim 18 wherein the number of transistors in the first stack is different than the number of transistors in the second stack.

21. The switch die of claim 18 further comprising a control circuit configured to support operations of the first stack, the second stack, and the intermediate shunt stack.

22. The switch die of claim 21 wherein the control circuit is configured to turn the first stack off, the second stack off, and the intermediate shunt stack on, when a low-power signal passes through the first node to a third node and it is desirable to isolate the second node from the first node.

23. The switch die of claim 21 wherein the control circuit is configured to turn the first stack off, the second stack off, and the intermediate shunt stack off, when a high-power signal passes through the first node to a third node and it is desirable to isolate the second node from the first node.

24. A switching module comprising:
a packaging substrate configured to receive a plurality of components; and
a switch assembly implemented on the packaging substrate and including a first stack and a second stack arranged in series between a first node and a second node, and defining an intermediate node between the first stack and the second stack, each stack including a respective number of transistors arranged in series, the switch assembly further including a switchable shunt path having a first end and a second end, the first end coupled to the intermediate node such that the switchable shunt path is capable of connecting the intermediate node to the second end.

25. (canceled)

26. (canceled)

27. (canceled)

28. (canceled)

29. (canceled)

30. (canceled)

31. (canceled)

32. (canceled)

33. (canceled)
